(19) United States
(12) Patent Application Publication
(10) Pub. No.: US 2025/0163581 A1
(43) Pub. Date: May 22, 2025

(54) DUAL PLENUM SHOWERHEAD WITH CENTER TO EDGE TUNABILITY

(71) Applicant: Lam Research Corporation, Fremont, CA (US)

(72) Inventor: Krishna Birru, Fremont, CA (US)

(73) Assignee: Lam Research Corporation, Fremont, CA (US)

(21) Appl. No.: 18/840,365

(22) PCT Filed: Feb. 13, 2023
(86) PCT No.: PCT/US2023/062484

§ 371 Date: Aug. 21, 2024

Related U.S. Application Data
(60) Provisional application No. 63/269,532, filed on Mar. 17, 2022.

(51) Int. Cl. C23C 16/455; H01J 37/32

(52) U.S. Cl. CPC C23C 16/45591; C23C 16/45565; C23C 16/45574; H01J 37/32449; H01J 2237/334

(57) ABSTRACT

A dual-zone process gas distribution showerhead is disclosed. In at least one embodiment, dual-zone showerhead comprises an inner zone and an outer zone surrounding the inner zone. At least a first plenum is within the first zone and coupled to a first gas inlet port. In at least one embodiment, outer zone comprises at least a second plenum coupled to a second gas inlet port. In at least one embodiment, first plenum is coupled to a first plurality of apertures within the inner zone. In at least one embodiment, second plenum is coupled to a second plurality of apertures in the outer zone.

### CLAIM OF PRIORITY

This application claims benefit of priority of U.S. Provisional Application No. 63/269,532 filed Mar. 17, 2022 title “Dual Plenum Showerhead With Center To Edge Tunability,” which is incorporated by reference in its entirety.

### BACKGROUND

Process tools are used to perform treatments such as deposition and etching of film on substrates like semiconductor wafers. For example, deposition may be performed to deposit a conductive film, a dielectric film, or other types of film using chemical vapor deposition (CVD), plasma enhanced CVD (PECVD), atomic layer deposition (ALD), plasma enhanced ALD (PEALD), and/or other deposition processes. The deposition may be performed in a wafer process tool such as a PECVD tool. Other processes, such as plasma etching processes, may also be performed in a wafer processing tool equipped with appropriate gases. The process tool may comprise multiple stations for processing more than one wafer at a time. The processes may be performed within a vacuum chamber maintained at high vacuum.

A process tool may be equipped with a process gas distribution manifold known as a showerhead, so named because of its resemblance to a household showerhead. The showerhead enables distribution of process gases into the vacuum chamber of the process tool. Process gases may be directed to the wafer that is positioned below the showerhead, generally mounted on a wafer pedestal. Currently, a process showerhead may issue one or more process gases at a uniform flow rate over the diameter of the showerhead. It may be desirable to tune the flow rate of the process gas or gases by providing separate gas delivery systems within the same showerhead.

### BRIEF DESCRIPTION OF THE DRAWINGS

Here, material is illustrated by way of example and not by way of limitation in the accompanying figures. For simplicity and clarity of illustration, elements illustrated in figures are not necessarily drawn to scale. For example, dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among figures to indicate corresponding or analogous elements.

FIG. 1A illustrates a cross-sectional view in xz plane of a dual-zone dual plenum gas distribution showerhead, according to at least one embodiment.

FIG. 1B illustrates a cross sectional view in yz plane of dual zone dual-plenum showerhead shown in FIG. 1A, according to at least one embodiment.

FIG. 1C illustrates a cross-sectional view in xz plane of a dual-zone, quad-plenum process gas distribution showerhead, according to at least one embodiment.

FIG. 2A illustrates a cross-sectional view in xz plane of a dual-zone, quad-plenum process gas distribution showerhead, according to at least one embodiment.

FIG. 2B illustrates a plan view in xy plane of dual-zone, quad-plenum process gas distribution showerhead shown in FIG. 2A, according to at least one embodiment.

FIG. 3A illustrates a cross-sectional view in yz plane of a dual-zone, quad-plenum process gas distribution showerhead, according to at least one embodiment.

FIG. 3B illustrates a plan view of dual-zone, quad-plenum process gas distribution showerhead shown in FIG. 3A, according to at least one embodiment.

FIG. 4 illustrates a profile view of a process tool comprising a dual-zone, dual plenum process gas distribution showerhead, according to at least one embodiment.

FIG. 5 illustrates a flow chart summarizing an exemplary method for operating a dual-zone, multi-plenum process gas distribution showerhead, according to at least one embodiment.

### DETAILED DESCRIPTION

Here, numerous specific details are set forth, such as structural schemes, to provide a thorough understanding of at least one embodiment. It will be apparent to one skilled in art that at least one embodiment may be practiced without these specific details. In other instances, well-known features, such as gas delivery line tubing fittings, heating elements and snap switches, are described in lesser detail to not unnecessarily obscure at least one embodiment. Furthermore, it is to be understood that at least one embodiment shown in a figure is an illustrative representation and are not necessarily drawn to scale.

In some instances, well-known methods and devices are shown in block diagram form, rather than in detail, to avoid obscuring present disclosure. Reference throughout this specification to “an embodiment,” “at least one embodiment,” or “one embodiment,” or “some embodiments,” means that a particular feature, structure, function, or characteristic described in connection with embodiment is included in at least one embodiment. Thus, appearances of phrase “in an embodiment,” or “in at least one embodiment,” or “in one embodiment,” or “some embodiments,” in various places throughout this specification are not necessarily referring to same embodiment of disclosure. Furthermore, particular features, structures, functions, or characteristics may be combined in any suitable manner in one or more embodiments. For example, a first embodiment may be combined with a second embodiment anywhere particular features, structures, functions, or characteristics associated with two embodiments are not mutually exclusive.

Here, “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical, electrical or in magnetic contact with each other, and/or that two or more elements co-operate or interact with each other (e.g., as in a cause an effect relationship).

Here, “over,” “under,” “between,” and “on” as used herein refer to a relative position of one component or material with respect to other components or materials where such physical relationships are noteworthy. Unless these terms are modified with “direct” or “directly,” one or more intervening components or materials may be present. Similar distinctions are to be made in context of component assemblies. As used throughout this description, and in claims, a list of items joined by term “at least one of” or “one or more of” can mean any combination of listed terms.

Here, “adjacent” here may generally refer to a position of a thing being next to (e.g., immediately next to or close to with one or more things between them) or adjoining another thing (e.g., abutting it).

Unless otherwise specified in explicit context of their use, terms “substantially equal,” “about equal” and “approximately equal” mean that there is no more than incidental variation between two things so described. Here, such variation is typically no more than +/−10% of referred value.

To address limitations described herein, a dual-zone, multiple-plenum showerhead is disclosed. In at least one embodiment, dual-zone, multi-plenum showerhead comprises an inner zone and an outer zone. In some embodiments, outer zone is in peripheral portion of showerhead surrounding inner zone. In at least one embodiment, inner zone may comprise one plenum or two plenums that are adjacent and confined within inner zone. In at least one embodiment, outer zone may comprise one plenum or two plenums that are adjacent and confined within outer zone. In at least one embodiment, showerhead may comprise up to four plenums, for example, two plenums in inner zone and two plenums in outer zone. In at least one embodiment, multiple plenums are fluidically isolated from one another so that gases having dissimilar compositions may be kept separate within showerhead and do not mix before exiting showerhead. In at least one embodiment, dual-zone showerhead may advantageously provide center-to-edge tunability of process gas flow rates and composition.

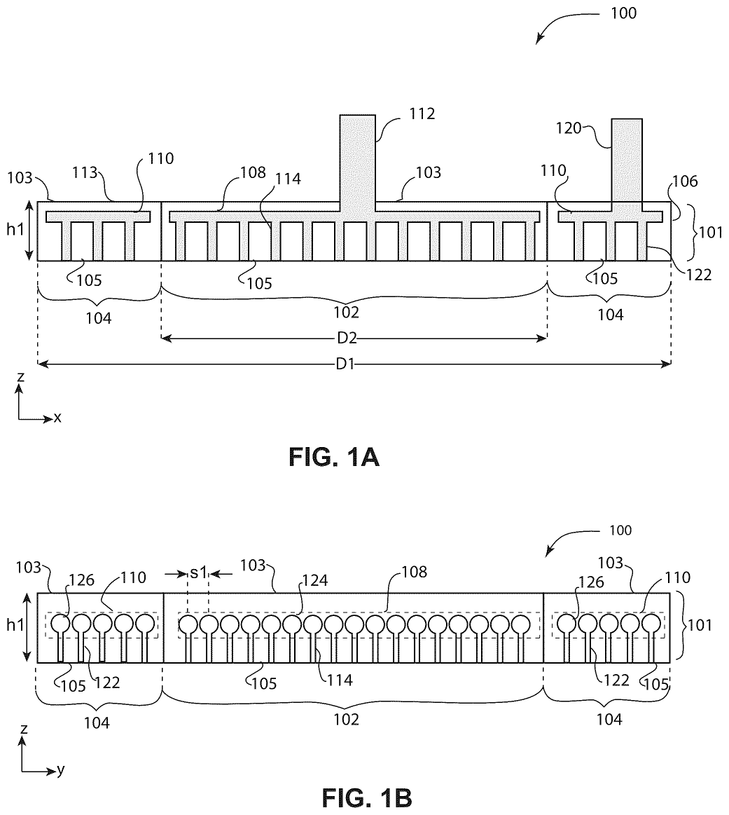

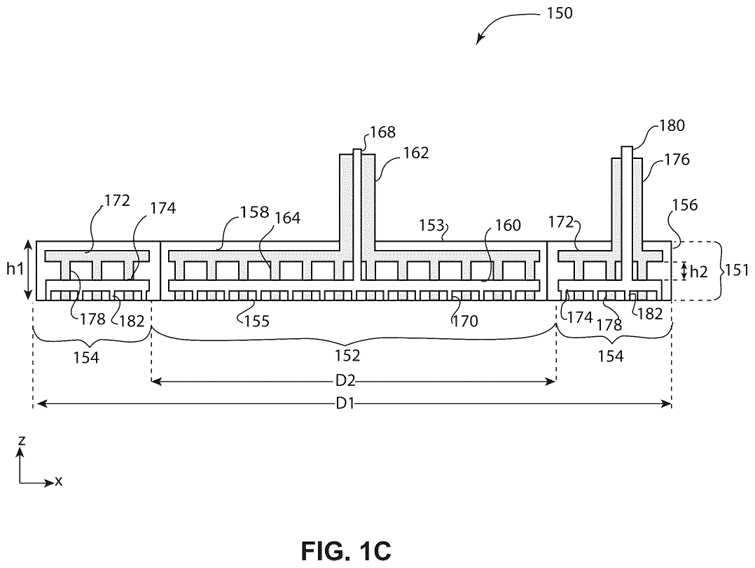

FIG. 1A illustrates a cross-sectional view in xz plane of a dual-zone, dual-plenum gas distribution showerhead (hereinafter showerhead 100) having a body 101 comprising inner zone 102 and outer zone 104, in accordance with at least one embodiment. In at least one embodiment, body 101 may also comprise upper surface 103 and lower surface 105. Here, “showerhead” may generally refer to a device resembling a household showerhead that sprays a fluid. In at least one embodiment, a showerhead distributes a process gas within a process chamber. In at least one embodiment, outer zone 104 is peripheral to inner zone 102. Here, “zone” may generally refer to a portion or region of body 101 in which a plenum distribution system may be confined. Here, “body” may generally refer to main structural component or shell of showerhead 100, having overall geometry of showerhead 100. In at least one embodiment, body 101 may be a solid structure in which fluidic substructures such as plena and apertures may be machined or formed additively for example by molding, casting or 3D printing. Here, “upper surface” and “lower surface” with reference to body 101 may generally refer to top and bottom boundaries of uppermost and lowermost portions, respectively, of body 101. In at least one embodiment, lower surface may comprise a plurality of apertures. In at least one embodiment, lower surface may be referred to as a “faceplate” (defined below). In at least one embodiment, upper surface and lower surface may be substantially smooth or may have a texture. In at least one embodiment, upper and lower surfaces may have relatively rough finish, for example from machining marks (e.g., a surface roughness of 10 microns or greater), or may have a polished finish, including a plated metal layer. Here, “inner zone” may generally refer to a zone in a central portion of a body, such as body of showerhead. Here, “outer zone” may generally refer to a peripheral region of a body of a showerhead. In at least one embodiment, showerhead 100 comprises body 101, where body 101 generally has a cylindrical geometry, comprising a height h₁ and a diameter D₁.

Here, “plenum” may generally refer to a distribution reservoir in form of a cavity, chamber or channel for containing or passing a fluid (e.g., a gas or liquid), to which multiple channels or apertures are fluidically coupled to distribute fluid. Here, “fluidically coupled” may generally refer to two fluid-bearing structures that are mechanically coupled such that a fluid may flow or distribute itself within both structures. In at least one embodiment, a pipe is fluidically coupled to a tank. Here, “plena” may generally refer to multiple plenums (e.g., plural for “plenum”). Here, “aperture” may generally refer to an opening within a wall or surface. In at least one embodiment, body 101 may comprise an assembly of parts. In at least one embodiment, body 101 may comprise a metal such as a chemically resistant aluminum alloy, a chemical resistant alloy of steel such as stainless steel or a Hastelloy, a ceramic material such as aluminum oxide, or a chemically resistant and heat resistant polymer such as Ultem polyimide, polyetherether ketone (PEEK), fluorinated hydrocarbons such as Teflon, PEF, FPA, etc.

In at least one embodiment, cylindrical geometry may have a circular cross-section that may be advantageously adapted to standard circular shapes of wafer substrates. In at least one embodiment, showerhead 100 may have a square or rectangular geometry (not shown), where D₁ may be replace by a width. Regarding showerhead 100, inner zone 102 has a diameter D₂, which is shown as a portion of D₁. It may be understood that diameter D₂ may not represent location of a physical edge or sidewall between inner zone 102 and outer zone 104. D₂ may rather be a construct to demark a region where fluid carrying structures contained within two zones may be absent.

In at least one embodiment, outer zone 104 has an annular geometry that extends between D₂ and sidewall 106 at D₁. In at least one embodiment, both central zone 102 and peripheral zone 104 have a single plenum distribution system. Here, “single plenum distribution system” may generally refer to one fluid distribution manifold within inner zone 102 and outer zone 104. In at least one embodiment, an individual plenum may comprise its own plurality of outlet apertures or nozzles. In at least one embodiment, an inner plenum 108 is confined within inner zone 102, whereas an outer plenum 110 is confined within outer zone 104.

In at least one embodiment, inner plenum 108 and outer plenum 110 are shown to be adjacent but separate, where inner plenum 108 is fluidically isolated from outer plenum 110. In at least one embodiment, inner plenum 108 and outer plenum 110 may each comprise extended unitary cavities within body 101. In at least one embodiment, outer plenum 110 may have an annular structure that surrounds inner plenum 108. In at least one embodiment, inner plenum 108 and/or outer plenum 110 comprise separate pluralities of channels that may be created by machining, for example, a series of parallel tunnels partially or completely through body 101.

In at least one embodiment, inner plenum 108 is fluidically coupled to inner inlet port 112 that extends through top surface 113 of body 101. In at least one embodiment, inner plenum 108 is also fluidically coupled to a first plurality of apertures 114. In at least one embodiment, inner inlet port 112, inner plenum 108 and apertures 114 form an inner fluid distribution manifold. In at least one embodiment, apertures 114 may extend between inner plenum 108 and a central portion of lower surface 105. In at least one embodiment, lower surface 105 comprises a faceplate.

In at least one embodiment, within outer zone 104, outer plenum 110 is fluidically coupled to outer inlet port 120 and to a second plurality of apertures 122. In at least one embodiment, outer inlet port 120, outer plenum 110 and apertures 122 form an outer fluid distribution manifold, where outer fluid distribution manifold is fluidically isolated from inner fluid distribution manifold. Here, “fluidically isolated” may generally refer to having no fluid path between two or more fluid-carrying structures, such as inner plenum 108 and outer plenum 110. In at least one embodiment, fluids within each structure may be isolated from one another. In at least one embodiment, apertures 122 may extend between outer plenum 110 and a peripheral portion of lower surface 105. Here, “faceplate” may generally refer to a lower surface of a process gas distribution showerhead, such as showerhead 100, comprising a plurality of apertures, such as apertures 114 and 122, arranged in a particular pattern. A plan view illustration of lower surface 105 is shown in FIG. 1B, in accordance with at least one embodiment. In at least one embodiment, inner plenum 108 and outer plenum 110 are mutually independent in that they are mechanically and fluidically decoupled from each other, being coupled instead to separate inner and outer inlet ports 112 and 120, respectively, and outlet apertures 114 and 122, respectively.

FIG. 1B illustrates a cross sectional view in yz plane of dual zone dual-plenum showerhead 100, according to at least one embodiment. In at least one embodiment, cross-sectional view of FIG. 1B is taken from a y-z plane cutting through body 101. In at least one embodiment, inner plenum 108, shown from perspective of y-z cross section, comprises a plurality of inner distribution channels 124, separated by a spacing s₁. Spacing s₁ may range from zero to 10 mm, where adjacent individual inner distribution channels 124 overlap, forming a contiguous inner plenum 108. In at least one embodiment, individuals of plurality of inner distribution channels 124 may be fluidically interconnected to one another.

In at least one embodiment, individual inner distribution channels 124 may be substantially coplanar, as shown. Here, “coplanar” may generally refer to structures that are substantially contained within a plane or at same z-height within a larger host structure, such as showerhead body 101. In at least one embodiment, central axes of three-dimensional inner distribution channels may be coplanar but have structure slightly above and below plane. In at least one embodiment, coplanarity may also be defined by multiple structures having same z-height over a reference plane, such as lower surface 105. In at least one embodiment, individual inner distribution channels 124 may be substantially parallel to one another. In at least one embodiment, cross-sectional plane of FIG. 1B does not include a view of inner inlet port 112. In at least one embodiment, apertures 114 fluidically coupled to inner distribution channels 124 may extend to a central portion of lower surface 105. In at least one embodiment, inner distribution channels 124 may be formed by machining into channels in body 101.

In at least one embodiment, outer zone 104 may comprise a second plurality of outer distribution channels 126. In at least one embodiment, individual channels of second plurality of outer distribution channels 126 (hereinafter outer distribution channels 126) may extend substantially parallel to inner distribution channels 124. In at least one embodiment, outer distribution channels 126 are coplanar with inner distribution channels 124.

In at least one embodiment, for inner distribution channels 124, outer distribution channels 126 may be fluidically coupled to one another by cross channels (not shown) or by overlapping diameters. In at least one embodiment, outer distribution channels 126 may be fluidically coupled to apertures 122, which extends to a peripheral portion of lower surface 105.

FIG. 1C illustrates a cross-sectional view of dual-zone, quad-plenum gas distribution showerhead 150 (hereinafter showerhead 150), comprising inner zone 152 and outer zone 154, in accordance with at least one embodiment. In at least one embodiment, outer zone 154 may be peripheral to inner zone 152, like showerhead 100 shown in FIG. 1A. In some embodiments, showerhead 150 comprises body 151, where body 151 generally has a cylindrical geometry, comprising height h₁ and diameter D₁, as described for showerhead 100 in FIG. 1A. In at least one embodiment, diameter D₁ may extend to sidewall 156, which extends between upper surface 153 and lower surface 155. In at least one embodiment, outer zone 154 surrounds inner zone 152 and is shown in figure as two cross section portions flanking inner zone 152.

In at least one embodiment, both central zone 152 and peripheral zone 154 have a dual plenum distribution system. Here, “dual plenum distribution system” may generally refer to two fluid distribution manifolds that may be adjacent to each other within a confined space. In at least one embodiment, an individual distribution manifold may comprise its own plurality of outlet apertures or nozzles coupled to its plenum. In at least one embodiment, a dual plenum distribution system may enable two independently controlled process gas feeds to enter a single showerhead.

In at least one embodiment, in context of showerhead 150, inner zone 152 comprises inner upper plenum 158 and inner lower plenum 160, both confined within inner zone 152. In at least one embodiment, inner upper plenum 158 and inner lower plenum 160 are shown in a stacked configuration, where inner upper plenum 158 is within a plane at z-height h₂ over a lower plane through which inner lower plenum 160 may extend. In at least one embodiment, inner upper plenum 158 and inner lower plenum 160 are fluidically isolated from one another. In at least one embodiment, inner upper plenum 158 and inner lower plenum 160 each comprise extended unitary cavities within body 151. In at least one embodiment, inner upper plenum 158 and/or inner lower plenum 160 comprise separate pluralities of channels (that may be created by machining, for example, a series of parallel tunnels partially or completely through body 151.

In at least one embodiment, inner upper plenum 158 is fluidically coupled to inlet 162 and to an inner plurality of apertures 164, forming an inner fluid distribution manifold. In at least one embodiment, apertures 164 may extend between inner upper plenum 158 and lower surface 155. In at least one embodiment, inner lower plenum 160 is fluidically coupled to inlet 168, which is on upper surface 153, and to a second plurality of apertures 170, forming a second fluid distribution manifold. In at least one embodiment, apertures 170 may extend between inner lower plenum 160 and lower surface 155. In at least one embodiment, distribution plena 158 and 160 are mutually independent in that they are mechanically and fluidically decoupled from each other, being coupled instead to separate inlets 162 and 168, respectively, and outlet apertures 164 and 170, respectively.

In at least one embodiment, apertures 164 may be interspersed between apertures 170, as shown, where apertures 164 and apertures 170 may be arranged in two interpenetrating arrays on lower surface 155. In at least one embodiment, apertures 164 and 170 may be arranged in two interpenetrating arrays, enabling an overlapped gas distribution coverage from showerhead 150. In at least one embodiment, gas species entering through inlets 162 and 168, respectively, may be independently controlled by separate mass flow controllers, for example. In at least one embodiment, inner zone 152 may include embedded heating elements to control temperature within inner zone 152.

In at least one embodiment, outer zone 154 comprises outer upper plenum 172 and outer lower plenum 174. In at least one embodiment, outer upper plenum 172 and outer lower plenum 174 are fluidically isolated from one another. In at least one embodiment, outer upper plenum 172 and outer lower plenum 174 may be contiguous cavities. In at least one embodiment, outer upper plenum 172 and outer lower plenum 174 may comprise pluralities of separate tunnels as described for inner upper plenum 158 and inner lower plenum 160. In at least one embodiment, a first outer zone distribution manifold may comprise outer upper plenum 172 fluidically coupled to outer inlet 176 and apertures 178. In at least one embodiment, a second outer zone distribution manifold may comprise outer lower plenum 174 fluidically coupled to inlet 180 and apertures 182.

In at least one embodiment, outer upper plenum 172 may extend within a plane at z-height h₃ above a lower plane through which outer lower plenum 174 may extend, as shown. In at least one embodiment, h₃ may be substantially equal to h₂. Like apertures 164 and 170 within inner zone 152, apertures 178 and 182 within outer zone 154 may be arranged within two interpenetrating arrays. In at least one embodiment, array geometry may be same for both interpenetrating arrays comprising apertures 178 and 182, respectively. In at least one embodiment, apertures 178 and apertures 182 may be arranged in two interpenetrating square arrays, where adjacent apertures 178 or 182 are equidistant from one another (e.g., apertures 178 and apertures 182 have same pitch). In at least one embodiment, other suitable geometries may equally be within scope of disclosure. In at least one embodiment, apertures 178 and 182 may be arranged in two interpenetrating hexagonal arrays.

In at least one embodiment, like inner zone 152, two independently controlled and separate process gas sources may be respectively coupled to outer zone inlet 176 and outer zone inlet 180 of first and second outer zone distribution manifolds, respectively. In at least one embodiment, overlapping sprays of two process gases may issue simultaneously from apertures 178 and apertures 182, respectively, within a confined area. In at least one embodiment, spray area may be defined by a wafer substrate below showerhead 150. While not shown in figure, in at least one embodiment, outer zone 154 may also comprise heating elements that are independent from heating elements within inner zone 152. In at least one embodiment, such heating elements may heat outer zone 154 independently from inner zone 152, enabling separate temperature control of both inner zone 152 and outer zone 154.

In at least one embodiment, while same or different process gases may be coupled to both inner zone 152 and outer zone 154, two process gases coupled to outer zone inlets 176 and 180 may be controlled independently from process gases coupled to inner zone inlets 162 and 168, enabling tuning of process gas flow and temperature across diameter D₁ of showerhead 150. In at least one embodiment, a first pair of process gases coupled to inner zone 152 may have a first composition, mass flow rate and temperature. In at least one embodiment, a second pair of process gases coupled to outer zone 154 may have a second composition, mass flow rate and temperature. In at least one embodiment, pair of process gases may include an inert gas such as argon or nitrogen, or a reactive gas such as oxygen, ammonia, or nitrous oxide. In at least one embodiment, second gas may comprise a vapor of a reactive precursor substance. In at least one embodiment, first process gas may have substantially same composition as second process gas, however they are adjusted to different mass or volumetric flow rates.

In at least one embodiment, showerhead 100 may enable center-to-edge tuning of first and second process gas flow rates and temperatures to optimize deposition or etch processes performed on a wafer substrate. Here, “tune” or “tuning” may generally refer to an action of adjustment of a parameter to optimize a process. In at least one embodiment, a process may be optimized if flow of process gas over periphery (e.g., outer portion) of a wafer is tuned by decreasing peripheral gas flow relative to flow of same process gas over inner portion of wafer. In at least one embodiment, showerhead 150 may afford ability to provide variable process gas compositions, flow rates and temperatures across diameter of a wafer.

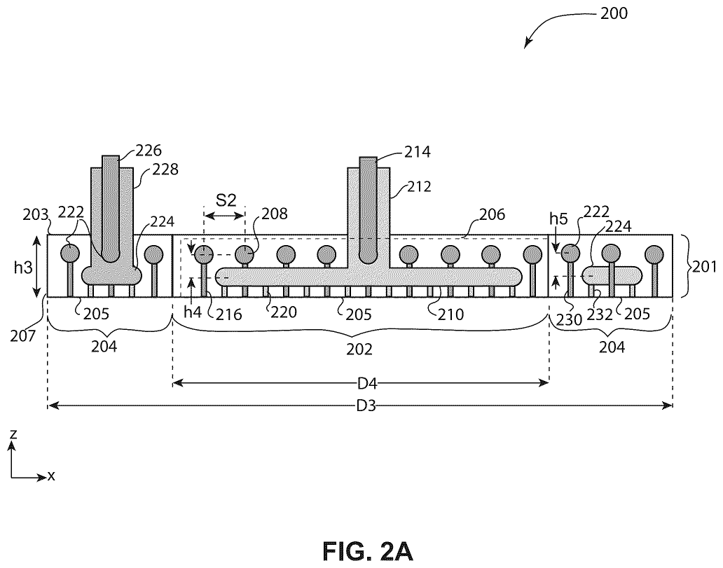

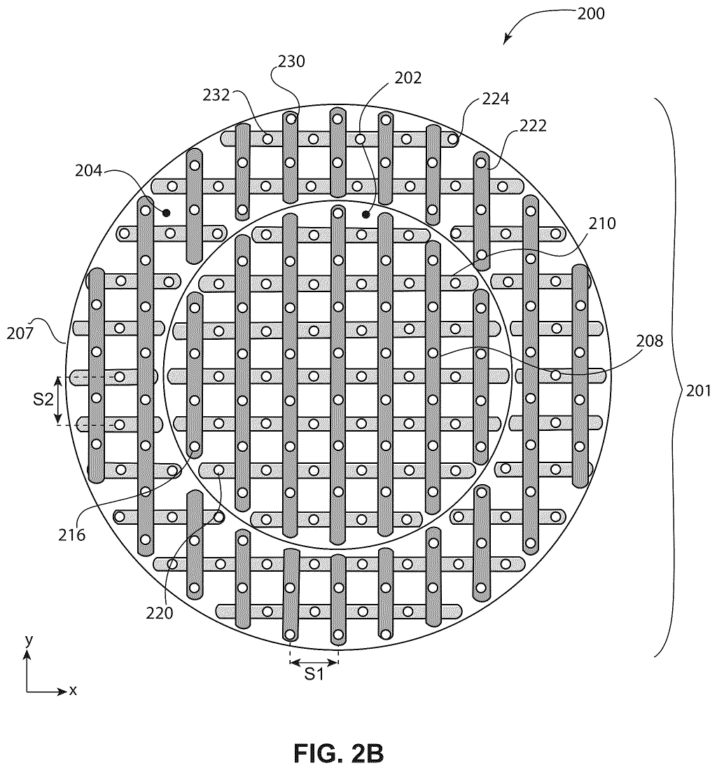

FIG. 2A illustrates a cross-sectional view in xz plane of dual-zone, quad-plenum gas distribution showerhead 200 (hereinafter showerhead 200), in accordance with at least one embodiment. In at least one embodiment, showerhead 200 comprises body 201. In at least one embodiment, body 201 comprises an inner zone 202 and an outer zone 204. In at least one embodiment, outer zone 204 surrounds inner zone 202, as shown in FIG. 2B. In at least one embodiment, body 201 further comprises upper surface 203 and lower surface 205. In at least one embodiment, lower surface 205 may be a faceplate of showerhead 200. In at least one embodiment, body 201 may have a cylindrical geometry (see FIG. 2B) having an overall diameter D₃ and height h₃. Diameter D₃ may extend to sidewall 207. In at least one embodiment, body 201 may have other suitable geometries, such as square or hexagonal. In at least one embodiment, while a demarcation between inner zone 202 and outer zone 204 is shown in figure, inner zone 202 and outer zone 204 may be contiguous within body 201. In at least one embodiment, a demarcation is shown for illustrative purposes only. In at least one embodiment, inner zone 202 may have a diameter D₄ that is a portion of D₃. In at least one embodiment, outer zone 204 may be an annular peripheral region of body 201 that surrounds inner zone 202. In at least one embodiment, in cross-sectional view of figure, outer zone 204 is divided into two cross sections flanking inner zone 202 but may be viewed as an annular portion on periphery of body 201. In at least one embodiment, an inner dual plenum system 206 (delineated in dashed enclosure) is contained within inner zone 202. In at least one embodiment, individual plena within dual plenum system 206 comprise a first plurality of inner distribution channels 208 and a second plurality of inner distribution channels 210. In at least one embodiment, individuals of first plurality of inner distribution channels 208 may be fluidically interconnected to one another, whereas individual channels of second plurality of inner distribution channels 210 may also be fluidically interconnected to one another, but fluidically isolated from distribution channels 208. In at least one embodiment, inner distribution channels 208 are shaded with a darker shade of gray than are inner distribution channels 210, which are shaded with a lighter shade of gray.

In at least one embodiment, while inner distribution channels 208 are shown to extend substantially orthogonally to inner distribution channels 210, they may also extend at oblique angles. In at least one embodiment, individual inner distribution channels 208 may be oriented parallel to each other, having horizontal spacing (e.g., in x-direction) s₁. In at least one embodiment, inner distribution channels 208 may be coplanar as shown. In at least one embodiment, individual inner distribution channels 210 may also be oriented parallel to each other and are also coplanar. In at least one embodiment, inner distribution channels 208 and inner distribution channels 210 may be within different planes of body 201, vertically separated by z-height h₄.

In at least one embodiment, inner distribution channels 208 may be formed by machining processes, such as drilling a series of long holes within body 201. In at least one embodiment, other methods may include milling inner distribution channels 208 in separate halves of body 201 and assembling two halves together into a unitary body 201. In at least one embodiment, inner distribution channels 208 are fluidically coupled to inner inlet port 212 on upper surface 203. Here, “inlet port” may generally refer to an opening on upper surface of showerhead 200 and provides a means of coupling showerhead to a tubing or hose that couples to a gas source.

In at least one embodiment, inner distribution channels 208 are fluidically interconnected. In at least one embodiment, one or more cross channels (not shown) may interconnect inner distribution channels 208. In at least one embodiment, while inner inlet port 212 is shown to be coupled to an individual channel among plurality of inner distribution channels 208 in cross-sectional view of figure, it may be interconnected to all individual channels of plurality of inner distribution channels 208. In at least one embodiment, spacing distance s1 may be decreased to allow adjacent inner distribution channels 208 to overlap with one another (similarly for inner distribution channels 210), enabling fluidic connectivity between adjacent channels.

In at least one embodiment, collectively, inner distribution channels 208 may be non-contiguous portions of a single upper plenum. In at least one embodiment, plurality of inner distribution channels 210 may be interconnected by one or more cross channels (not shown) and may be non-contiguous portions of a single lower plenum. In at least one embodiment, inner distribution channels 210 may be fluidically coupled to inner inlet port 214.

In at least one embodiment, inner distribution channels 208 are fluidically coupled to apertures 216, which extend below inner distribution channels 208 to lower surface 205. In at least one embodiment, inner distribution channels 210 are fluidically coupled to apertures 220, which also extends to lower surface 205. In at least one embodiment, apertures 216 and 220 provide outlets for process gases entering dual plenum system through inner inlet ports 212 and 214. In at least one embodiment, apertures 216 may be arranged in a first array having a square, hexagonal, or other suitable geometry, while apertures 220 may be arranged in a second array that interpenetrates first array of apertures 216. In at least one embodiment, arrays may extend in two dimensions on lower surface 205. Here, “aperture” may generally refer to openings that extend through faceplate of showerhead and are coupled to inner inlet ports 212 and 214. In at least one embodiment, apertures may act as individual nozzles through which process gases may issue as collective jets that may merge and flow over wafer substrate below.

In at least one embodiment, outer zone 204 may comprise a third plurality of outer distribution channels 222 and a fourth plurality of outer distribution channels 224. In at least one embodiment, individual channels of third plurality of outer distribution channels 222 may extend substantially orthogonal to individual channels of fourth plurality of outer distribution channels 224 (hereinafter outer distribution channels 224). In at least one embodiment, outer distribution channels 222 may run at oblique angles to outer distribution channels 224. In some embodiments, outer distribution channels 222 are coplanar within a first plane. In at least one embodiment, outer distribution channels 224 may be coplanar within a second plane that is separated from first plane by z-height h₅. In at least one embodiment, h₅ may be same as h₄.

In at least one embodiment, as described for inner distribution channels 208 and 210, outer distribution channels 222 may be fluidically coupled to one another by cross channels (not shown). In at least one embodiment, outer distribution channels 224 may be likewise interconnected. In at least one embodiment, outer distribution channels 222 are fluidically coupled to outer inlet port 226 and apertures 230, whereas outer distribution channels 224 are fluidically coupled to outer inlet port 228 and apertures 232. In at least one embodiment, apertures 230 and 232 extend to openings on lower surface 205.

FIG. 2B illustrates a plan view in xy plane of dual-zone quad-plenum showerhead 200, showing cross patterning of inner distribution channels 208 and 210, and outer distribution channels 222 and 224, in accordance with at least one embodiment. Cross-sectional plane may cut through inner distribution channels 208, and outer distribution channels 222. While not in a same plane, inner distribution channels 210 and outer distribution channels 224, both in lower planes, are shown for illustrative purposes. In at least one embodiment, outer zone 204 comprises an annular section of periphery of body 201 that surrounds inner zone 202. In at least one embodiment, inner distribution channels 208 and 210 extend in parallel to one another, respectively, but channels 208 run in orthogonal directions with respect to channels 210 (e.g., x and y directions, respectively). In at least one embodiment, inner distribution channels 208 may run at oblique angles with respect to inner distribution channels 210. To aid viewing of figure, inner distribution channels 208 are shaded by a darker shade of gray than used in shading of inner distribution channels 210. In at least one embodiment, inner distribution channels 208 are in a higher vertical plane than inner distribution channels 210, which are below plane of figure.

In at least one embodiment, as noted previously, individual inner distribution channels 208 and individual inner distribution channels 210 may be interconnected to adjacent channels 208 and 210, respectively, by cross channels. In at least one embodiment, interconnecting cross channels are not shown, for clarity. In at least one embodiment, spacing s₁ between inner distribution channels 208 and spacing s₂ between inner distribution channels 210 may be reduced to allow overlap between adjacent channels. In at least one embodiment, inner distribution channels 208 are fluidically isolated from inner distribution channels 210. In at least one embodiment, inner distribution channels 208 and inner distribution channels 210 are blind channels, where they do not intersect sidewall 207. In at least one embodiment, channels 208 and 210 may intersect sidewall 207, and may having openings in sidewall 207.

In at least one embodiment, outer distribution channels 222 and 224 are arranged similarly in outer zone 204. In at least one embodiment, outer distribution channels 222 extend in parallel to one another within plane of figure in which they are coplanar. In at least one embodiment, outer distribution channels 224 extend in parallel to one another within a plane below plane of figure in which they are coplanar. In at least one embodiment, outer distribution channels 224 are orthogonal to outer distribution channels 222 as shown but may also extend in oblique directions with respect to channels 222. In at least one embodiment, outer distribution channels 222 and outer distribution channels 224 are blind channels, having no intersections with exterior sidewalls. In at least one embodiment, some or all individual inner distribution channels 222 and/or inner distribution channels 224 may have intersections with exterior sidewalls.

In at least one embodiment, within inner zone 202, apertures 216 and 220 are shown in plan view, which extends below inner distribution channels 208 and 210, respectively, shown by white openings. In at least one embodiment, apertures 216 may alternate where inner distribution channels 208 cross inner distribution channels 210. In at least one embodiment, inner distribution channels 210, running horizontally in plane view (e.g., in x-direction), may include additional apertures 220 that are hidden in view by inner distribution channels 208 running in y-direction. In at least one embodiment, apertures 216 and 220 are distributed into two interpenetrating square arrays because of equidistant spacing between apertures and equidistant orthogonal spacing s₁ and s₂ between distribution channels. In at least one embodiment, apertures 216 and 220 may be distributed in arrays of other suitable geometries, such as a hexagonal geometry.

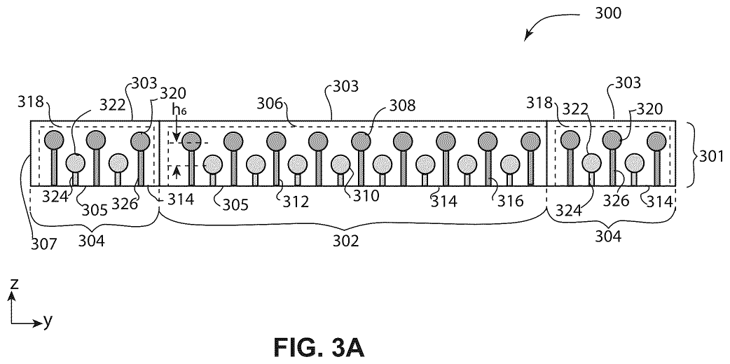

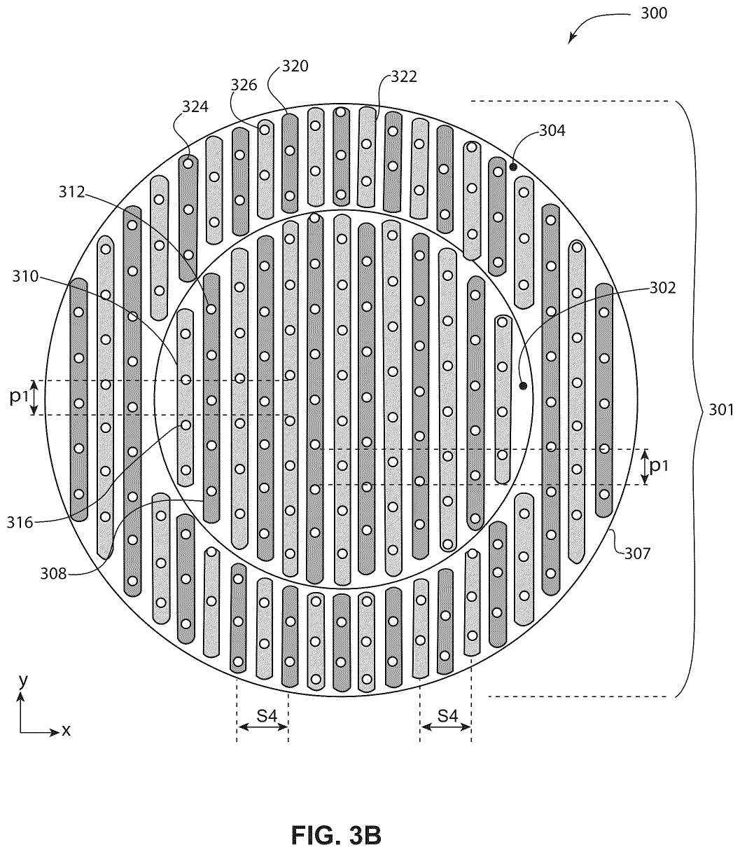

FIG. 3A illustrates a cross sectional view in yz plane of dual-zone, quad plenum showerhead 300 (hereinafter showerhead 300), comprising body 301 subdivided into inner zone 302 and outer zone 304, where outer zone 304 surrounds inner zone 302, as shown in FIG. 3B, in accordance with at least one embodiment. In at least one embodiment, body 301 comprises upper surface 303 and lower surface 305. In at least one embodiment, showerhead 300 may be substantially like showerhead 200. In at least one embodiment, body 301 may have a cylindrical geometry (e.g., sec FIG. 2B), and may have dimensions like showerheads 100 or 200. In at least one embodiment, while a demarcation between inner zone 302 and outer zone 304 is shown in cross-sectional view of FIG. 3A, inner zone 302 and outer zone 304 may be contiguous regions within body 301, where outer zone 304 may be an annular peripheral region of body 301 that surrounds inner zone 302. In at least one embodiment, demarcation line is shown for illustrative purposes.

In at least one embodiment, an inner dual plenum system 306 (delineated in dashed enclosure) is contained within inner zone 302. In at least one embodiment, individual plena within dual plenum system 306 comprise a first plurality of inner distribution channels 308 that may extend within an upper plane within inner zone 302, and a second plurality of inner distribution channels 310 that may extend within a lower plane within inner zone 302. In at least one embodiment, inner distribution channels 308 and inner distribution channel 310 may be non-coplanar. In at least one embodiment, individuals of first plurality of inner distribution channels 308 may be fluidically interconnected to one another, whereas individual channels of second plurality of inner distribution channels 310 may also be fluidically interconnected to one another, but fluidically isolated from distribution channels 308. Here, inner distribution channels 308 are shaded with a darker shade of gray than arc inner distribution channels 310, which are shaded with a lighter shade of gray.

In at least one embodiment, individual inner distribution channels 308 may be substantially coplanar within an upper plane, as shown. In at least one embodiment, individual inner distribution channels 308 may be substantially parallel to one another. In at least one embodiment, individual inner distribution channels 310 may be coplanar within a lower plane and substantially parallel to one another and to inner distribution channels 308. In at least one embodiment, upper plane and lower plane may be separated by z-height h₆. In at least one embodiment, inner distribution channels may be fluidically coupled to one another by cross channels (not shown) or overlapping diameters as described earlier.

In at least one embodiment, cross-sectional view of FIG. 3A may not include inlet ports as they may be substantially same as inner inlet ports 212 and 214 shown in FIG. 2A. In at least one embodiment, apertures 312 fluidically coupled to inner distribution channels 308 may extend between inner distribution channels 308 and lower surface 305. In at least one embodiment, apertures 312 may be substantially same as apertures 216 shown in FIG. 2A. In at least one embodiment, apertures 316 are fluidically coupled to inner distribution channels 310 and may also extend between inner distribution channels 310 and faceplate 314. In at least one embodiment, inner distribution channels 308 and inner distribution channels 310 may be formed by machining into channels in body 301.

In at least one embodiment, an outer dual plenum system 318 is contained within outer zone 304 and is indicated by dashed enclosures in both left and right sections of outer zone 304. In at least one embodiment, outer zone 304 may comprise a third plurality of outer distribution channels 320 that may extend within an upper plane within outer zone 304. In at least one embodiment, a fourth plurality of outer distribution channels 322 may extend within a lower plane within outer zone 304. In at least one embodiment, upper plane may be separated from lower plane by z-height h₆. In at least one embodiment, h₆ may be same as h₅. In at least one embodiment, outer distribution channels 320 may be substantially non-coplanar with outer distribution channels 322, as shown. In at least one embodiment, individual channels of third plurality of outer distribution channels 320 may extend substantially parallel to individual channels of fourth plurality of outer distribution channels 322 (hereinafter outer distribution channels 322). In at least one embodiment, outer distribution channels 320 are coplanar with inner distribution channels 308. In at least one embodiment, outer distribution channels 322 may be coplanar with inner distribution channels 310.

In at least one embodiment, as described for inner distribution channels 308 and 310, outer distribution channels 320 may be fluidically coupled to one another by cross channels (not shown). In at least one embodiment, outer distribution channels 322 may be likewise interconnected. In at least one embodiment, outer distribution channels 320 are fluidically coupled to an outer inlet port (not shown in cross-sectional plane of figure). In at least one embodiment, an outer inlet port (not shown) fluidically coupled to outer distribution channels 320 may be substantially like outer inlet port 226 shown in FIG. 2A, for example. In at least one embodiment, outer distribution channels 320 may be fluidically coupled to apertures 324, which extend to lower surface 305. In at least one embodiment, outer distribution channels 322 may be fluidically coupled to apertures 326, which also extend to lower surface 305.

FIG. 3B illustrates a plan view of dual-zone, quad-plenum showerhead 300. As noted, outer zone 304 comprises an annular section of periphery of body 301 that surrounds inner zone 302, in accordance with at least one embodiment. In at least one embodiment, inner distribution channels 308 may extend within a plane that is vertically displaced from a lower plane in which inner distribution channels 310 may extend. In at least one embodiment, outer distribution channels 308 and 320 are in plane of figure, while inner distribution channels 310 and outer distribution channels 322 are below plane of figure. In at least one embodiment, plane view shows inner distribution channels 308 and 310 that extend in parallel with respect to one another. In at least one embodiment, outer distribution channels 320 and 322 also extend in parallel with respect to one another. Here, to aid eye in distinguishing between upper and lower channels, inner distribution channels 308 and outer distribution channels 320 are shaded in a dark shade of gray, whereas inner distribution channels 310 and outer distribution channels 322 are shaded in a lighter gray.

In at least one embodiment, individual inner distribution channels 308 and individual inner distribution channels 310 may be respectively interconnected to adjacent channels that are coplanar. Cross channels (not shown) may be employed to interconnect adjacent coplanar channels. In at least one embodiment, spacing s₄ between inner distribution channels 308 and/or spacing s₄ between inner distribution channels 310 may be reduced to allow merging of adjacent channels to form a contiguous plenum. In at least one embodiment, while channels may merge, pitch p₁ between adjacent apertures 312, 316, 324, and 326 may be maintained at a desired pitch. In at least one embodiment, inner distribution channels 308 are fluidically isolated from inner distribution channels 310. In at least one embodiment, outer distribution channels 320 and outer distribution channels 322 are similarly isolated. In at least one embodiment, inner distribution channels 308 and 310, as well as outer distribution channels 320 and 322, may be blind channels. In at least one embodiment, channels 308 and 310 may intersect exterior sidewalls, for example forming openings in sidewall 307.

In at least one embodiment, in plan view of FIG. 3B, apertures 312 and 316, indicated by open circles, extend below inner distribution channels 308 and 310, respectively. In at least one embodiment, apertures 312 may have a regular pitch p1 that is same for apertures 316. In at least one embodiment, apertures 312 and 316 are distributed in two interpenetrating square arrays because of equidistant spacing (e.g., pitch p₁) between apertures. In at least one embodiment, apertures 312 and 316 may be arranged in any suitable geometry. In at least one embodiment, apertures 324 and 326 are also distributed in two interpenetrating square arrays. In at least one embodiment, apertures 324 and apertures 326 may be distributed in arrays of other suitable geometries, such as a hexagonal geometry.

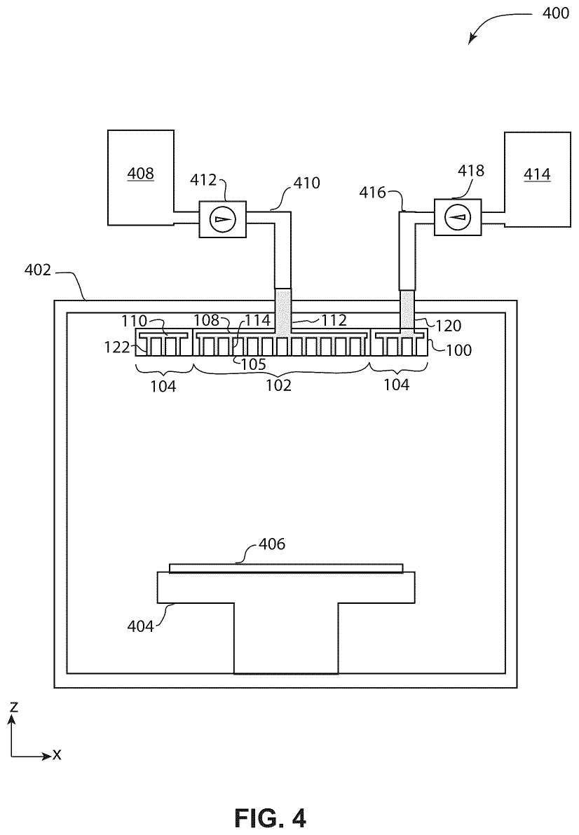

FIG. 4 illustrates a profile view of process tool 400, in accordance with at least one embodiment. In at least one embodiment, process tool 400 comprises vacuum chamber 402. Included within vacuum chamber 402 is showerhead 100. Here, “process tool” may generally refer to an instrument comprising a vacuum chamber, in which semiconductor wafers may be placed for processing. Here, “vacuum chamber” may generally refer to a large vessel, interior of which may be evacuated to a high vacuum to support semiconductor devices (and other devices comprising other materials amenable to similar processing), and processing operations using high vacuum, such as CVD and plasma etching processes to take place within. While illustrated embodiment shows showerhead 100, in at least one embodiment, 200 or 300 may be equally shown. In at least one embodiment, wafer chuck 404 is also included within vacuum chamber 402. Here, “wafer chuck” may generally refer to a mechanism comprising a stage for mounting a wafer substrate undergoing processing. In at least one embodiment, wafer chuck may include a vacuum clamp or electrostatic clamp for securing wafer substrate to the wafer chuck. Here, “wafer substrate” may generally refer to a semiconductor wafer, generally ranging in size between 3 cm and 50 cm. In at least one embodiment, wafer substrate 406 is mounted on wafer chuck 404. In at least one embodiment, wafer chuck may generally be positioned below showerhead 100, as shown. In at least one embodiment, showerhead 100 is a dual zone showerhead comprising inner zone 102 and outer zone 104. In at least one embodiment, inner zone 102 comprises plenum 108, where plenum 108 is fluidically coupled to inner inlet port 112 and apertures 114. In at least one embodiment, a first process gas source 408 is fluidically coupled to inner inlet port 112 through gas delivery line 410.

Here, “process gas source” may generally refer to a pressurized vessel or collection of vessels containing inert and reactive gases and vapors. Here, “gas” may generally refer to a substance that is in gas phase at room temperature. Here “vapor” may generally refer to a substance that is in gas phase by heating solid or liquid substance to an elevated temperature. In at least one embodiment, vapor generally must be maintained at an elevator temperature above vaporization temperature to prevent condensation.

In at least one embodiment, process gas source 408 comprises one or more pressurized gas tanks or vessels. In at least one embodiment, process gas source 408 may contain a process gas composed of one or more gaseous substances, for example, an inert gas (e.g., argon, nitrogen), and/or a reactive gas such as oxygen, ammonia, etc. In at least one embodiment, process gas source 408 may also be heated to an elevated temperature to maintain sublimated or otherwise vaporized reactive precursor vapors. In at least one embodiment, multiple process gas sources may be fluidically coupled to gas delivery line 410. A flow controller 412 may be included in-line with gas delivery line 410 to control mass or volumetric flow rate of process gas flowing within. Here, “gas delivery line” may generally refer to a tubing or pipe carrying flowing gases from a source to a device or chamber. In at least one embodiment, other flow control components may be included. Here, “flow controller” may generally refer to a fluid flow control device, such as a simple valve, a mass flow controller or a volumetric flow controller. In at least one embodiment, flow controller may also refer to a complex assembly of multiple gas conditioning components. In at least one embodiment, flow controller 412 may be part of a gas box, for example, comprising multiple valves, filters, mixers, heating elements, etc. to precondition process gas.

In at least one embodiment, a second process gas source 414 may be fluidically coupled to outer inlet port 120 through gas delivery line 416. In at least one embodiment, process gas source 414 may also comprise one or more pressurized gas tanks or vessels containing one or more gases and/or vapors as described for process gas source 408. In at least one embodiment, flow controller 418 may be included in-line with gas delivery line 416. In at least one embodiment, flow controller 418 may provide same functions as flow controller 412. In at least one embodiment, flow controller 412 may be operated independently from flow controller 418 to provide separately controlled process gas flows to inner zone 102 and outer zone 104 of showerhead 100. In at least one embodiment, during operation, at least one process gas may issue from separate sets of apertures, comprising apertures 114 in inner zone 102 and apertures 122 in outer zone 104. In at least one embodiment, advantageously, flow rates of process gas flowing through apertures 114 and 122 may be adjusted by tuning flow controllers 412 and 418, respectively. In at least one embodiment, tuned process gas flows may enable optimized delivery of process gases over inner and outer portions of wafer substrate 406.

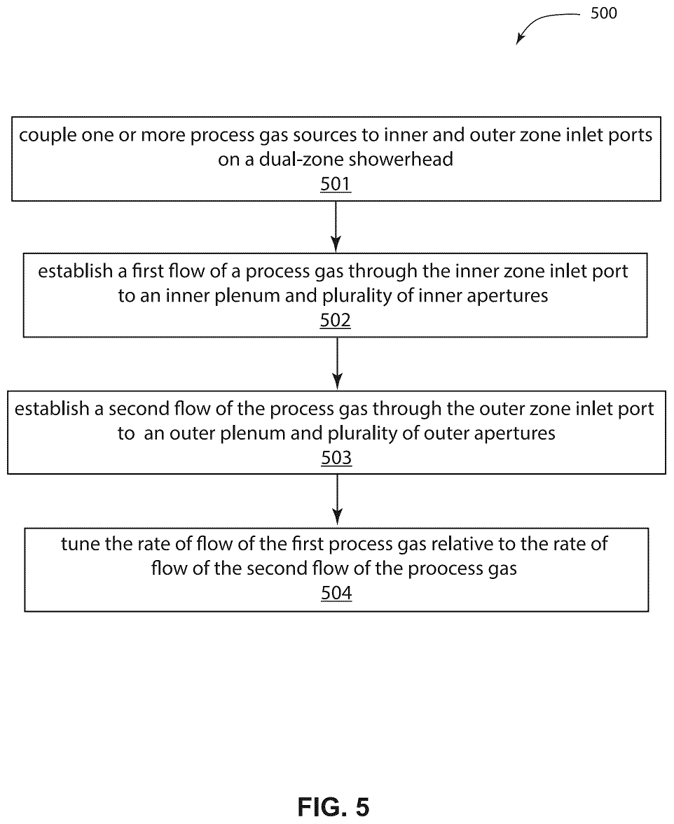

FIG. 5 illustrates a process flow chart 500 summarizing an exemplary method for using a dual zone, multiple plenum process gas distribution showerhead, such as any of showerheads 100, 200, or 300, in accordance with at least one embodiment. In at least one embodiment, at operation 501, a process tool, such as process tool 400 shown in FIG. 4, may be provided for processing one or more wafer substrates, such as wafer substrate 406 shown in FIG. 4. In at least one embodiment, process tool may comprise a vacuum chamber comprising a wafer chuck for mounting a wafer substrate within a region of vacuum chamber, as described earlier. In at least one embodiment, wafer chuck may be positioned directly under a process gas distribution showerhead (hereinafter “showerhead”). In at least one embodiment, showerhead may be a dual-zone, multi-plenum showerhead.

In at least one embodiment, showerhead may comprise an inner zone and an outer zone (e.g., inner zone 102 and outer zone 104, shown in FIG. 1A), comprising an inner inlet port and an outer inlet port, (e.g., inner inlet port 112 and outer inlet port 120 shown in FIG. 1A) respectively. In at least one embodiment, within inner zone, inner inlet port may be fluidically coupled to an inner plenum. In at least one embodiment, inner plenum may be fluidically coupled to a first plurality of apertures on an inner region of lower surface of showerhead (e.g., lower surface 105, shown in FIG. 1A). In at least one embodiment, within outer zone, outer inlet port may be fluidically coupled to an outer plenum. In at least one embodiment, outer plenum may be fluidically coupled to a second plurality of apertures on a periphery of lower surface, which may comprise a faceplate. In at least one embodiment, first plurality of apertures and second plurality of apertures may be operable to distribute process gases over a wafer substrate. In at least one embodiment, apertures may function as nozzles, directing gas flow downward over a wafer substrate that is positioned directly below faceplate of showerhead, as shown in FIG. 4.

Continuing to refer to operation 501, in at least one embodiment, a first process gas delivery line is connected to inner inlet port and a second process gas delivery line is connected to outer inlet port. In at least one embodiment, first gas delivery line may be fluidically coupled to a first process gas source. In at least one embodiment, second gas delivery line may be fluidically coupled to same first process gas source or to a second process gas source that contains a different gas than first process gas source. In at least one embodiment, first and second process gas sources may comprise one or more pressurized vessels containing inert or reactive gases and/or vapors. In at least one embodiment, first and second process gases may have substantially same composition, according to some embodiments. In at least one embodiment, first and second process gases may have substantially different compositions.

In at least one embodiment, at operation 502, a first flow of a process gas is established through a first gas delivery line coupled to inner inlet port on gas distribution showerhead. In at least one embodiment, inner inlet port is coupled to an inner plenum (e.g., plenum 108), which is coupled to a set of inner apertures (e.g., apertures 122 shown in FIG. 1A) In at least one embodiment, process gas may flow out into vacuum chamber through inner apertures. In at least one embodiment, inner apertures may function as nozzles, directing gas flow downward toward a center region of wafer substrate below.

In at least one embodiment, at operation 503, a second flow of same or a different process gas is established through second gas delivery line coupled to a second plenum (e.g., outer plenum 110 shown in FIG. 1A). In at least one embodiment, second plenum is fluidically coupled to a set of outer apertures in periphery of faceplate. In at least one embodiment, same process gas or a different process gas may flow through outer apertures and into vacuum chamber, being directed by nozzle behavior of outer apertures to peripheral region of wafer substrate below.

In at least one embodiment, at operation 504, rates of flow of process gases passing through inner and outer apertures may be tuned to optimize a CVD or etch process performed on wafer substrate. In at least one embodiment, advantageously, dual-zone showerhead provides for center-to-edge tuning of process gas flow rate over wafer substrate. In at least one embodiment, tuning process may be performed by adjustment of a first flow controller coupled to first gas delivery line. In at least one embodiment, a second flow controller may be coupled to second gas delivery line for independent tuning of second gas flow.

Following examples are provided that illustrate at least one embodiment. The examples can be combined with other examples. As such, at least one embodiment can be combined with at least another embodiment without changing scope of at least one embodiment.

Example 1 is a gas distribution showerhead, comprising a body that comprises an upper surface, a lower surface, an inner zone, and an outer zone, wherein the outer zone surrounds the inner zone, a first plenum within the inner zone, wherein the first plenum is fluidically coupled to a first inlet port over the upper surface, and a second plenum within the outer zone, wherein the second plenum is fluidically coupled to a second inlet port over the upper surface, wherein the first plenum is fluidically coupled to a first plurality of apertures, wherein the first plurality of apertures is within a central portion of the lower surface, wherein the second plenum is fluidically coupled to a second plurality of apertures, and wherein the second plurality of apertures is within a peripheral portion of the lower surface.

Example 2 includes all features of example 1, wherein the first plenum comprises a first chamber within the inner zone, and wherein the second plenum comprises a second chamber within the outer zone.

Example 3 includes all features of example 2, further comprising a third plenum within the inner zone, wherein the third plenum is fluidically coupled to a third inlet port and to a third plurality of apertures.

Example 4 includes all features of example 3, wherein the third plurality of apertures is within the central portion of the lower surface.

Example 5 includes all the features of example 4, further comprising a fourth plenum within the outer zone, wherein the fourth plenum is fluidically coupled to a fourth inlet port and to a fourth plurality of apertures.

Example 6 includes all features of example 5, wherein the fourth plurality of apertures is within the peripheral portion of the lower surface.

Example 7 includes all the features of example 6, wherein the first plenum comprises a first plurality of channels within the inner zone, and wherein the second plenum comprises a second plurality of channels within the outer zone.

Example 8 includes all features of example 7, wherein individual ones of the first plurality of channels are substantially parallel to one another, and wherein individual ones of the second plurality of channels are substantially parallel to one another.

Example 9 includes all features of example 8, wherein the third plenum comprises a third plurality of channels within the inner zone.

Example 10 includes all features of example 9, wherein individual ones of the third plurality of channels are substantially parallel to one another.

Example 11 includes all features of example 10, wherein the individual ones of the first plurality of channels are substantially coplanar with the individual ones of the third plurality of channels.

Example 12 includes all features of example 10, wherein the individual ones of the first plurality of channels are substantially non-coplanar with the individual ones of the third plurality of channels.

Example 13 includes all features of example 12, wherein the individual ones of the first plurality of channels are substantially coplanar within a first plane within the inner zone, wherein the individual ones of the third plurality of channels are substantially coplanar within a second plane within the inner zone, and wherein the first plane is above the second plane.

Example 14 includes all features of example 13, wherein the individual ones of the first plurality of channels are substantially parallel to the individual ones of the third plurality of channels.

Example 15 includes all features of example 13, wherein the individual ones of the first plurality of channels are substantially orthogonal to the individual ones of the third plurality of channels.

Example 16 includes all features of example 9, wherein the fourth plenum comprises a fourth plurality of channels within the outer zone.

Example 17 includes all features of example 16, wherein individual ones of the fourth plurality of channels are substantially parallel to one another.

Example 18 includes all features of example 17, wherein the individual ones of the second plurality of channels are substantially coplanar with the individual ones of the fourth plurality of channels.

Example 19 includes all features of example 17, wherein the individual ones of the second plurality of channels are substantially non-coplanar with the individual ones of the fourth plurality of channels.

Example 20 includes all features of example 19, wherein the individual ones of the second plurality of channels are substantially coplanar within a third plane within the outer zone, wherein the individual ones of the fourth plurality of channels are substantially coplanar within a fourth plane within the outer zone, and wherein the third plane is above the fourth plane.

Example 21 includes all features of example 20, wherein the individual ones of the second plurality of channels are substantially parallel to the individual ones of the fourth plurality of channels.

Example 22 includes all features of example 20, wherein the individual ones of the second plurality of channels are substantially orthogonal to the individual ones of the fourth plurality of channels.

Example 23 is a system comprising a process tool that comprises a vacuum chamber and a gas distribution showerhead within the vacuum chamber, wherein the gas distribution showerhead comprises a body that includes an upper surface; a lower surface, an inner zone; and an outer zone, wherein the outer zone surrounds the inner zone, a first plenum within the inner zone, wherein the first plenum is fluidically coupled to a first inlet port over the upper surface, and a second plenum within the outer zone, wherein the second plenum is fluidically coupled to a second inlet port over the upper surface, wherein the first plenum is fluidically coupled to a first plurality of apertures, wherein the first plurality of apertures is within a central portion of the lower surface, wherein the second plenum is fluidically coupled to a second plurality of apertures, and wherein the second plurality of apertures is within a peripheral portion of the lower surface.

Example 24 includes all features of example 23, wherein the first plenum is fluidically coupled to a first process gas source and the second plenum is fluidically coupled to a second process gas source.

Example 25 includes all features of example 24, wherein a first flow controller is between the first process gas source and the first plenum, wherein a second flow controller is between the second process gas source and the second plenum, and wherein the first flow controller is operable to tune a flow rate of a first process gas and the second flow controller is operable to tune a flow rate of a second process gas.

Example 26 is a method for using a gas distribution showerhead, comprising flowing a first process gas from a first process gas source coupled to a first plenum of a gas distribution showerhead, flowing a second process gas from a second process gas source coupled to a second plenum of the gas distribution showerhead, tuning a first flow rate of the first process gas through the first plenum of the gas distribution showerhead, and tuning a second flow rate of the second process gas through the second plenum of the gas distribution showerhead, wherein the gas distribution showerhead comprises a body that comprises an upper surface, a lower surface, an inner zone; and an outer zone, wherein the outer zone surrounds the inner zone, a first plenum within the inner zone, wherein the first plenum is fluidically coupled to a first inlet port over the upper surface, and a second plenum within the outer zone, wherein the second plenum is fluidically coupled to a second inlet port over the upper surface, wherein the first plenum is fluidically coupled to a first plurality of apertures, wherein the first plurality of apertures is within a central portion of the lower surface, wherein the second plenum is fluidically coupled to a second plurality of apertures, and wherein the second plurality of apertures is within a peripheral portion of the lower surface.

Example 27 includes all features of example 26, wherein the first process gas is substantially identical to the second process gas.

Example 28 includes all features of example 27, further comprising flowing a third process gas from a third process gas source coupled to a third plenum, wherein the third plenum is adjacent to the first plenum within the inner zone.

Example 29 includes all features of example 28, further comprising flowing a fourth process gas from a fourth process gas source coupled to a fourth plenum, wherein the fourth plenum is adjacent to the second plenum within the outer zone.

Example 30 includes all features of example 29, wherein the third process gas is substantially identical to the fourth process gas, wherein the first process gas source is coupled to the first plenum and the second plenum, and wherein the second process gas source is coupled to the third plenum and the fourth plenum.

Example 31 includes all features of example 30, wherein flowing the first process gas from the first process gas source comprises flowing the first process gas through the first plenum and the second plenum, and wherein flowing the second process gas from the second process gas source comprises flowing the second process gas through the third plenum and the fourth plenum.

Besides what is described herein, various modifications may be made to at least one embodiment thereof without departing from their scope. Therefore, illustrations of at least one embodiment herein should be construed as examples, and not restrictive to scope of at least one embodiment. Here, scope of at least one embodiment should be measured by reference to claims that follow.

What is claimed is:

1. A gas distribution showerhead, comprising:
a body that comprises an upper surface, a lower surface, an inner zone, and an outer zone, wherein the outer zone surrounds the inner zone;
a first plenum within the inner zone, wherein the first plenum is coupled to a first inlet port over the upper surface; and
a second plenum within the outer zone, wherein the second plenum is coupled to a second inlet port over the upper surface,
wherein the first plenum is coupled to a first plurality of apertures, wherein the first plurality of apertures is within a central portion of the lower surface, wherein the second plenum is coupled to a second plurality of apertures, and wherein the second plurality of apertures is within a peripheral portion of the lower surface.

2. The gas distribution showerhead of claim 1, wherein the first plenum comprises a first chamber within the inner zone, and wherein the second plenum comprises a second chamber within the outer zone.

3. The gas distribution showerhead of claim 2, further comprising a third plenum within the inner zone, wherein the third plenum is coupled to a third inlet port and to a third plurality of apertures.

4. The gas distribution showerhead of claim 3, wherein the third plurality of apertures is within the central portion of the lower surface.

5. The gas distribution showerhead of claim 4, further comprising a fourth plenum within the outer zone, wherein the fourth plenum is coupled to a fourth inlet port and to a fourth plurality of apertures.

6. The gas distribution showerhead of claim 5, wherein the fourth plurality of apertures is within the peripheral portion of the lower surface.

7. The gas distribution showerhead of claim 6, wherein the first plenum comprises a first plurality of channels within the inner zone, and wherein the second plenum comprises a second plurality of channels within the outer zone.

8. The gas distribution showerhead of claim 7, wherein individual ones of the first plurality of channels are substantially parallel to one another, and wherein individual ones of the second plurality of channels are substantially parallel to one another.

9. The gas distribution showerhead of claim 8, wherein the third plenum comprises a third plurality of channels within the inner zone.

10. The gas distribution showerhead of claim 9, wherein individual ones of the third plurality of channels are substantially parallel to one another.

11. The gas distribution showerhead of claim 10, wherein the individual ones of the first plurality of channels are substantially coplanar with the individual ones of the third plurality of channels.

12. The gas distribution showerhead of claim 10, wherein the individual ones of the first plurality of channels are substantially non-coplanar with the individual ones of the third plurality of channels.

13. The gas distribution showerhead of claim 12, wherein the individual ones of the first plurality of channels are substantially coplanar within a first plane within the inner zone, wherein the individual ones of the third plurality of channels are substantially coplanar within a second plane within the inner zone, and wherein the first plane is above the second plane.

14. The gas distribution showerhead of claim 13, wherein the individual ones of the first plurality of channels are substantially parallel to the individual ones of the third plurality of channels.

15. The gas distribution showerhead of claim 13, wherein the individual ones of the first plurality of channels are substantially orthogonal to the individual ones of the third plurality of channels.

16. The gas distribution showerhead of claim 9, wherein the fourth plenum comprises a fourth plurality of channels within the outer zone.

17. The gas distribution showerhead of claim 16, wherein individual ones of the fourth plurality of channels are substantially parallel to one another.

18. The gas distribution showerhead of claim 17, wherein the individual ones of the second plurality of channels are substantially coplanar with the individual ones of the fourth plurality of channels.

19. The gas distribution showerhead of claim 17, wherein the individual ones of the second plurality of channels are substantially non-coplanar with the individual ones of the fourth plurality of channels.

20. The gas distribution showerhead of claim 19, wherein the individual ones of the second plurality of channels are substantially coplanar within a third plane within the outer zone, wherein the individual ones of the fourth plurality of channels are substantially coplanar within a fourth plane within the outer zone, and wherein the third plane is above the fourth plane.

21. The gas distribution showerhead of claim 20, wherein the individual ones of the second plurality of channels are substantially parallel to the individual ones of the fourth plurality of channels.

22. The gas distribution showerhead of claim 20, wherein the individual ones of the second plurality of channels are substantially orthogonal to the individual ones of the fourth plurality of channels.

23. A system, comprising:
a process tool that comprises a vacuum chamber; and
a gas distribution showerhead within the vacuum chamber, wherein the gas distribution showerhead comprises:
a body that includes an upper surface; a lower surface, an inner zone; and an outer zone, wherein the outer zone surrounds the inner zone;
a first plenum within the inner zone, wherein the first plenum is coupled to a first inlet port over the upper surface; and
a second plenum within the outer zone, wherein the second plenum is coupled to a second inlet port over the upper surface,
wherein the first plenum is coupled to a first plurality of apertures, wherein the first plurality of apertures is within a central portion of the lower surface, wherein the second plenum is coupled to a second plurality of apertures, and wherein the second plurality of apertures is within a peripheral portion of the lower surface.

24. The system of claim 23, wherein the first plenum is coupled to a first process gas source and the second plenum is coupled to a second process gas source.

25. (canceled)

26. A method for using a gas distribution showerhead, comprising:
flowing a first process gas from a first process gas source coupled to a first plenum of the gas distribution showerhead;
flowing a second process gas from a second process gas source coupled to a second plenum of the gas distribution showerhead;
tuning a first flow rate of the first process gas through the first plenum of the gas distribution showerhead; and
tuning a second flow rate of the second process gas through the second plenum of the gas distribution showerhead, wherein the gas distribution showerhead comprises a body that comprises an upper surface, a lower surface, an inner zone; and an outer zone, wherein the outer zone surrounds the inner zone;
wherein the first plenum is within the inner zone, wherein the first plenum is coupled to a first inlet port over the upper surface; and
wherein the second plenum is within the outer zone, wherein the second plenum is coupled to a second inlet port over the upper surface,
wherein the first plenum is coupled to a first plurality of apertures, wherein the first plurality of apertures is within a central portion of the lower surface,
wherein the second plenum is coupled to a second plurality of apertures, and wherein the second plurality of apertures is within a peripheral portion of the lower surface.

27. (canceled)

28. (canceled)

29. (canceled)

30. (canceled)

31. (canceled)
